(19) United States
(12) Patent Application Publication
(10) Pub. No.: US 2026/0332077 A1
(43) Pub. Date: Oct. 22, 2026

(54) METHOD FOR MEASURING CURRENT USING SINGLE CURRENT SENSOR IN THREE-PHASE MOTOR CONTROL SYSTEM

(71) Applicant: VCTECH CO., LTD., Gunpo-si, Gyeonggi-do (KR)

(72) Inventor: Yong Kyun LEE, Uiwang-si, Gyeonggi-do (KR)

(73) Assignee: VCTECH CO., LTD., Gunpo-si, Gyeonggi-do (KR)

(21) Appl. No.: 19/337,927

(22) Filed: Sep. 24, 2025

(30) Foreign Application Priority Data
Apr. 17, 2025 (CN) 10-2025-0050223

(51) Int. Cl. H02P 21/22; G01R 19/00

(52) U.S. Cl. CPC H02P 21/22; G01R 19/0092

(57) ABSTRACT

Proposed is a method for measuring current using a single current sensor in a three-phase motor control system, capable of effectively reducing noise by making the current sensing timing constant, wherein the method includes calculating a PWM duty ratio of each phase on the basis of a carrier signal of an up-counter method and a three-phase voltage command, applying a PWM signal to each phase for a predetermined measurement time at a start time of the carrier signal on the basis of the PWM duty ratio of each phase, and correcting the PWM signal of each phase for a predetermined correction time according to the predetermined measurement time within one PWM cycle.

### CROSS REFERENCE TO RELATED APPLICATION

The present application claims priority to Korean Patent Application No. 10-2025-0050223 filed on Apr. 17, 2025, the entire contents of which are incorporated herein for all purposes by this reference.

### BACKGROUND

### Technical Field

Exemplary embodiments of the present disclosure relate to a method for measuring current using a single current sensor in a three-phase motor control system.

### Description of the Related Art

In general, three or two current sensors are employed for controlling a three-phase motor. A system using a single current sensor to drive a three-phase motor has been developed in order to reduce manufacturing costs. For example, as illustrated in FIG. 1, a three-phase motor control system using a single current sensor may control a motor by installation of a single current sensor in a direct current link (DC-link) and by restoration of three-phase current information (I_{U}, I_{V}, I_{W}) applied to the motor from the current measured by the single current sensor.

In order to control the three-phase current, the reference voltage, the voltage that serves as the basis for motor control, is changed, and then is implemented by using the Space Vector Pulse Width Modulation (SVPWM) method. When applying this space vector PWM method, there is an unmeasurable region in which the current cannot be measured with the reference voltage vector, and an area between sectors in FIG. 2 is an unmeasurable region. Therefore, in preparation for entering such an unmeasurable region, there is a method of changing the reference voltage vector.

When changing the reference voltage vector in a conventional manner, a ripple may occur in the reference voltage vector, which may cause current ripple or speed ripple in the motor, resulting in noise. The occurrence of such motor noise has become a limiting factor in the use of three-phase motor control systems using a single current sensor.

### RELATED ART DOCUMENTS

### [Patent Document]

(Patent Document 1) Korean Patent No. 10-0776255 (Data of Patent: Nov. 7, 2007, “System For Controlling 3-Phase Motor Using SingleDC-link Current Sensor”, Samsung Electronics Co., Ltd.)

### SUMMARY

A task to be solved by the present disclosure aims to provide a method for measuring current using a single current sensor in a three-phase motor control system. However, such a task is merely illustrative and does not limit the scope of the present disclosure.

According to one aspect of the present disclosure, a method for measuring current using a single current sensor in a three-phase motor control system includes calculating a PWM duty ratio of each phase on the basis of a carrier signal of an up-counter method and a three-phase voltage command, applying a PWM signal to each phase for a predetermined measurement time at a start time of the carrier signal on the basis of the PWM duty ratio of each phase, and correcting the PWM signal of each phase for a predetermined correction time according to the predetermined measurement time within one PWM cycle.

The applying the PWM signal may include applying the PWM signal to a first phase having the longest duty length based on the PWM duty ratio of each phase for a time equal to twice a predetermined minimum current measurement time at the start time of the carrier signal.

The correcting the PWM signal may include not applying a previously scheduled PWM signal to the first phase for a time equal to one multiple of the predetermined minimum current measurement time after the start time of the carrier signal.

The applying the PWM signal may include applying the PWM signal to a second phase having an intermediate duty length based on the PWM duty ratio of each phase for a time equal to one multiple of a predetermined minimum current measurement time at the start time of the carrier signal.

The applying the PWM signal may include not applying the PWM signal to a third phase having the shortest duty length based on the PWM duty ratio of each phase at the start time of the carrier signal.

The correcting the PWM signal may include applying the PWM signal additionally to the third phase for a time equal to one multiple of a predetermined minimum current measurement time after the start time of the carrier signal.

Other aspects, features, and advantages in addition to those described above will become apparent from the specific details, claims, and drawings for implementing the following disclosure.

According to an exemplary embodiment of the present disclosure configured as described above, there is provided a method for measuring current using a single current sensor in a three-phase motor control system capable of effectively reducing noise by making the current sensing timing constant. It is obvious that the scope of the present disclosure is not limited by such an effect.

### BRIEF DESCRIPTION OF THE DRAWINGS

FIG. 1 is a view illustrating an example of a three-phase motor control system.

FIG. 2 is a view illustrating an unmeasurable region in which a motor cannot be driven using a single current sensor.

FIG. 3 is a flowchart illustrating a method for measuring current according to an exemplary embodiment of the present disclosure.

FIGS. 4A to 4F are views illustrating a method of applying and correcting PWM signals according to an exemplary embodiment of the present disclosure.

FIG. 5 is a view illustrating a method of applying and correcting PWM signals in a low-speed driving mode and a normal driving mode according to an exemplary embodiment of the present disclosure.

### DETAILED DESCRIPTION OF THE DISCLOSURE

The present disclosure may be modified in various ways and may have various exemplary embodiments, and specific exemplary embodiments may be illustrated in the drawings and described in detail in the detailed description. Effects and features of the present disclosure and methods for achieving them will become apparent with reference to exemplary embodiments described in detail along with the drawings below. However, the present disclosure may not be limited to exemplary embodiments disclosed below, but may be implemented in various forms.

Hereinafter, exemplary embodiments of the present disclosure will be described in detail with reference to the accompanying drawings, and when referring to the drawings, the same reference numerals will be assigned to the same or corresponding components, and redundant descriptions thereof will be omitted.

In the following exemplary embodiments, terms such as “first” and “second” may not be used in a limiting sense, but rather distinguish one component from another. Also, singular expressions may include plural expressions unless the context clearly indicates otherwise. In addition, terms such as “include” or “have” may merely signify the existence of features or components described in the specification, and do not preclude the possibility that one or more other features or components may be added.

For convenience of explanation, the sizes of the components may be exaggerated or reduced in the drawings. For example, the size and thickness of each component shown in the drawing may be arbitrarily illustrated for convenience of explanation, and thus the present disclosure may not necessarily be limited to those shown.

In the following exemplary embodiment, when a part such as an area, component, unit, block, or module is described as being on or above another part, it may encompass not only cases in which it is directly on another part but also cases in which other areas, components, units, blocks, or modules are interposed therebetween. Also, when an area, component, unit, block, or module is connected, it may encompass not only cases in which other areas, components, units, blocks, or modules are directly connected, but also cases in which other areas, components, units, blocks, or modules are interposed therebetween and indirectly connected.

Hereinafter, various exemplary embodiments of the present disclosure will be described in detail with reference to the accompanying drawings so that those skilled in the art to which the present disclosure pertains can easily practice the present disclosure.

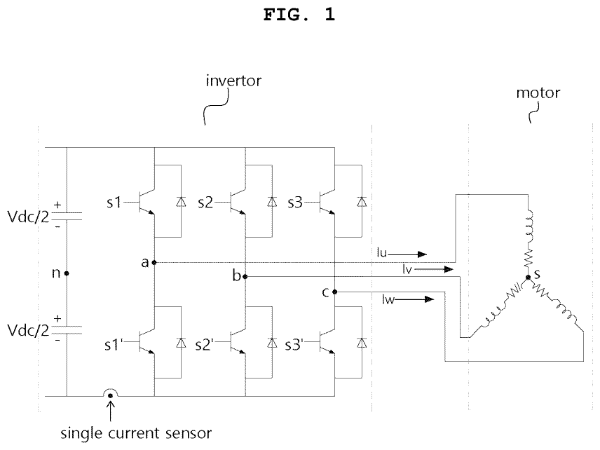

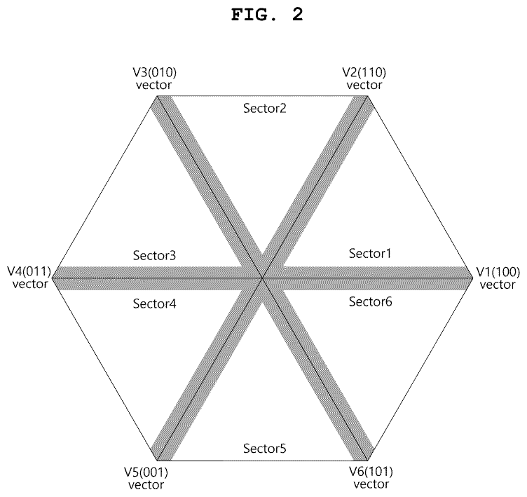

A three-phase motor control system according to the present disclosure can apply the same configuration as illustrated in FIG. 1, in which a single current sensor is installed in a direct current (DC) link at a lower side of a capacitor. In the case of restoring a three-phase current from the current measured by the single current sensor, a minimum current measurement time (Tₘᵢₙ) may be required for current measurement, so the motor driving by a three-phase inverter may be impossible when the reference voltage vector is in the unmeasurable region of FIG. 2.

For example, the minimum current measurement time (Tₘᵢₙ) may be composed of a sum of a time (T_{dead}) for preventing a short circuit, a time (Tₛₑₜ) taken for the ringing of the current generated at the time of switching to end, and a time (Tₛₐₘₚ) required for converting an analog signal into a digital signal. In this case, the current cannot be detected in the area where the sum of the application times of the zero vector and the active vector is shorter than the minimum current measurement time (Tₘᵢₙ).

When supplying voltage to the three-phase motor by using SVPWM (Space Vector PWM) or general PWM in the three-phase inverter, the PWM duty ratio of each phase may be determined. However, the current sensing (measurement) may be required in the motor control, and in order to measure the current, PWM signals need to be adjusted so that the current sensor can operate at specific moments. To this end, an additional PWM operation for sensing may be required, and during this process, the originally calculated PWM duty ratio may be distorted.

For the current sensing, a switching state needs to be maintained for a specific time (e.g., at least a minimum current measurement time (Tₘᵢₙ)), and for this purpose, the adjustment of PWM duty may be required. However, when such adjustment of PWM duty is performed, line-to-line voltages (e.g., V_{ab}, V_{bc}, V_{ca}) originally intended may be distorted, so that the originally designed space vector modulation (SVPWM) pattern is not maintained, and the magnitude and direction of an actual voltage vector may change. Accordingly, it is necessary to compensate for such distorted line-to-line voltages.

According to the present disclosure, the purpose of line-to-line voltage compensation may be to correct changes which occur because the PWM signal for the current sensing is added to conventionally calculated PWM duties, in magnitudes of the line-to-line voltages, V_{ab}, V_{bc}, and V_{ac}. For example, according to the present disclosure, the PWM duty may be readjusted so as to maintain the conventional magnitude and direction of the voltage vector.

According to the present disclosure, the adjustment and readjustment of the PWM duty may be performed through the control of switches with respect to the transistors (s1, s2, s3, s1′, s2′, and s3′) of the inverter illustrated in FIG. 1. In this case, in the method for measuring current according to the present disclosure, the currents of two phases may be measured using the single current sensor, and the current of the remaining one phase may be calculated through the sum of the currents of the three phases. For example, in the three phases of the U phase, the V phase, and the W phase, when the phase currents of the U phase and the V phase are measured, the phase current of the W phase may be calculated using the sum of the three phases.

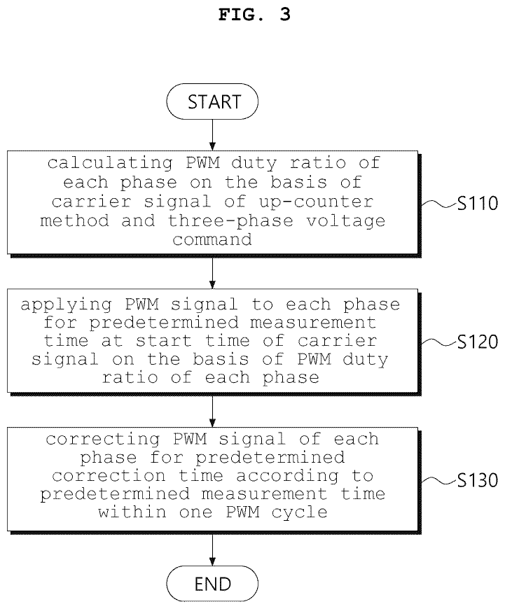

FIG. 3 is a flowchart illustrating a method for measuring current according to an exemplary embodiment of the present disclosure.

Referring to FIG. 3, in a method of measuring current using a single current sensor in a three-phase motor control system according to an exemplary embodiment of the present disclosure, the three-phase motor control system according to an exemplary embodiment of the present disclosure may calculate the PWM duty ratio of each phase on the basis of a carrier signal of an up-counter method and a three-phase voltage command in the step S110.

For example, the carrier signal in the PWM generation method according to the present disclosure may be configured in an up-counter method. In this case, according to the present disclosure, the timing for the current sensing may be constantly maintained.

In the step S120, the three-phase motor control system according to an exemplary embodiment of the present disclosure may apply the PWM signal to each phase for a predetermined measurement time at the start time of the carrier signal on the basis of the PWM duty ratio of each phase.

The three-phase motor control system according to an exemplary embodiment of the present disclosure can apply the PWM signal to a first phase having the longest duty length based on the PWM duty ratio of each phase for a time equal to twice a predetermined minimum current measurement time at the start time of the carrier signal. For example, the predetermined minimum current measurement time (Tₘᵢₙ) may be composed of a sum of a time (T_{dead}) for preventing a short circuit, a time (Tₛₑₜ) taken for the ringing of the current generated at the time of switching to end, and a time (Tₛₐₘₚ) required for converting an analog signal into a digital signal. For example, when the PWM signal is applied for the time equal to twice the predetermined minimum current measurement time, the PWM signal may be applied for a time of 2 Tₘᵢₙ.

The three-phase motor control system according to an exemplary embodiment of the present disclosure may apply the PWM signal to the second phase having an intermediate duty length based on the PWM duty ratio of each phase for a time equal to one multiple of a predetermined minimum current measurement at the start time of the carrier signal. For example, when the PWM signal is applied for the time equal to one multiple of the predetermined minimum current measurement, the PWM signal may be applied for a time of 1 Tₘᵢₙ.

The three-phase motor control system according to an exemplary embodiment of the present disclosure may not apply the PWM signal to a third phase having the shortest duty length based on the PWM duty ratio of each phase at the start time of the carrier signal. In this case, when the PWM signal is not applied, the current measurement may not be performed.

In the step S130, the three-phase motor control system according to an exemplary embodiment of the present disclosure may correct the PWM signal of each phase for a predetermined correction time according to the predetermined measurement time within one PWM cycle.

For example, the three-phase motor control system according to an exemplary embodiment of the present disclosure may not apply a previously scheduled PWM signal to the first phase for a time equal to one multiple of the predetermined minimum current measurement time after the start time of the carrier signal. In this case, the three-phase motor control system according to an exemplary embodiment of the present disclosure may subtract the PWM signal for the time equal to one multiple of the predetermined minimum current measurement time within one PWM cycle.

For example, the three-phase motor control system according to an exemplary embodiment of the present disclosure may apply additional PWM signals to the third phase for a time equal to one multiple of the predetermined minimum current measurement time after the start time of the carrier signal. In this case, the three-phase motor control system according to an exemplary embodiment of the present disclosure may add the PWM signals for the time equal to one multiple of the predetermined minimum current measurement time within one PWM cycle.

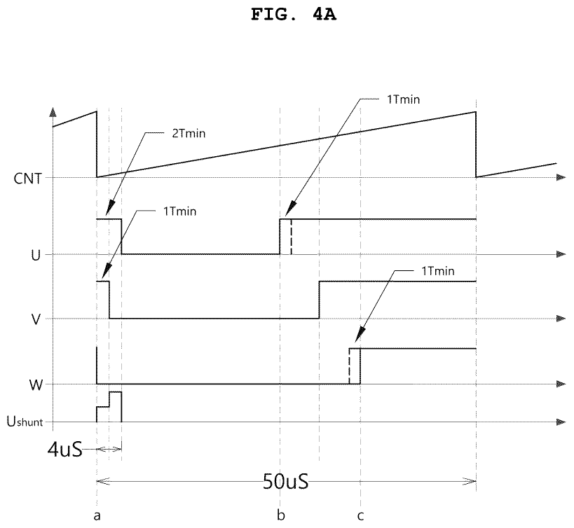

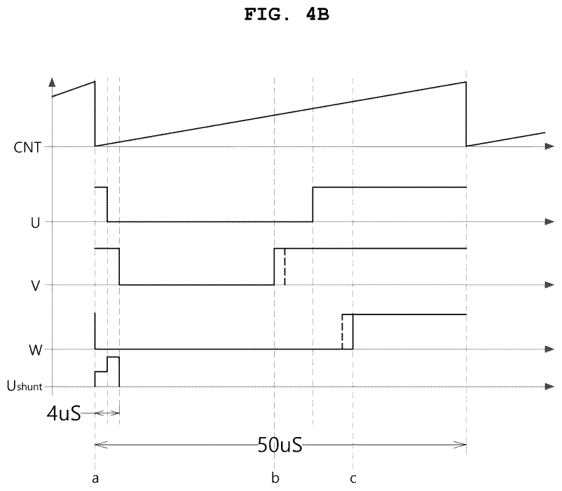

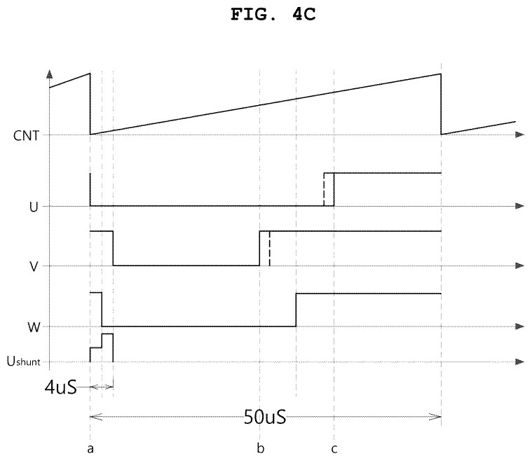

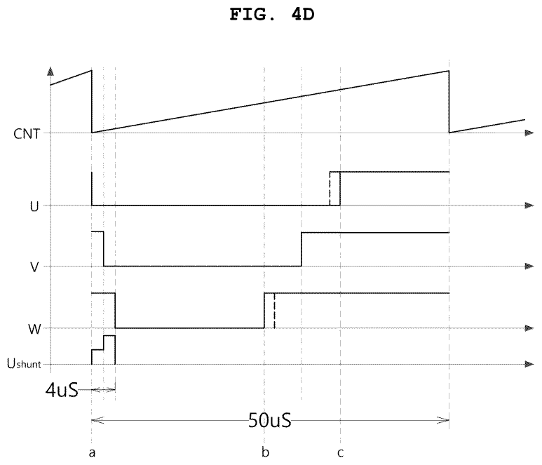

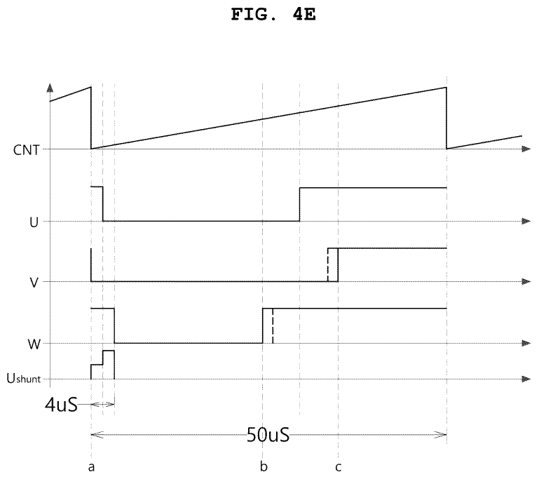

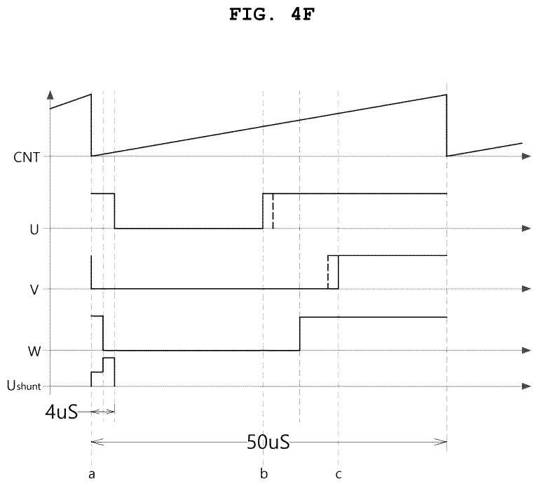

FIGS. 4A to 4F are views illustrating a method of applying and correcting PWM signals according to an exemplary embodiment of the present disclosure.

According to the present disclosure, PWM signals may be applied to two phases at a start time of carrier signals in the up-counter method so that the currents of the two phases can be measured. In addition, according to the present disclosure, the PWM duty ratio of each phase may be calculated on the basis of the carrier signal of the up-counter method and the three-phase voltage command, so that a phase with the longest duty length, a phase with an intermediate duty length, and a phase with the shortest duty length can be selected.

Referring to FIG. 4A, an order of PWM duty lengths may be determined in the order of U-phase, V-phase, and W-phase. Referring to FIG. 2 together, this case may correspond to the sector 1, wherein the PWM signal for measuring current may be output to the U phase and the V phase in the sector 1 and since the effective voltage vectors are 110 and 100, the currents −I_{w} and I_{U} may be measured and I_{V} may be calculated through the sum of the three phases.

For example, referring to FIG. 4A, the PWM signal may be applied to the U phase having the longest PWM duty length for a time equal to twice (2Tₘᵢₙ) a predetermined minimum current measurement time at the start time (a) of the carrier signal (CNT). In addition, the previously scheduled PWM signal may not be applied to the U phase for a time equal to one multiple (1Tₘᵢₙ) of the predetermined minimum current measurement time after the start time of the carrier signal. For example, the PWM signal may not be applied at the time (b), at which the previously scheduled PWM signal is applied, after the start time of the carrier signal, but the PWM signal may be applied at the time b+1Tₘᵢₙ.

In addition, the PWM signal may be applied to the V phase having an intermediate PWM duty length for a time equal to one multiple (1Tₘᵢₙ) of the predetermined minimum current measurement time at the start time (a) of the carrier signal (CNT).

In addition, the PWM signal may not be applied to the W phase having the shortest PWM duty length at the start time (a) of the carrier signal (CNT). In addition, the PWM signal may be additionally applied to the W phase for a time equal to one multiple (1 Tₘᵢₙ) of a predetermined minimum current measurement time after the start time of the carrier signal. For example, the PWM signal may be applied at the time, c−1Tₘᵢₙ, which precedes a time point (c), at which a previously scheduled PWM signal is applied, after the start time of the carrier signal.

Referring to FIG. 4B, an order of PWM duty lengths may be determined in the order of V-phase, U-phase, and W-phase. Referring to FIG. 2 together, this case may correspond to the sector 2, wherein PWM signals for current measurement may be output to the V phase and the U phase in the section 2 and since the effective voltage vectors are 110 and 010, the currents −I_{w} and I_{V} may be measured and I_{U} may be calculated through the sum of the three phases.

Referring to FIG. 4C, an order of PWM duty lengths may be determined in the order of V-phase, W-phase, and U-phase. Referring to FIG. 2 together, this case may correspond to the sector 3, wherein PWM signals for measuring current may be output to the V-phase and the W-phase in the section 3 and since effective voltage vectors are 011 and 010, the currents −I_{U} and I_{V} may be measured and I_{W} may be calculated through the sum of the three phases.

Referring to FIG. 4D, an order of PWM duty lengths may be determined in the order of W phase, V phase, and U phase. Referring to FIG. 2 together, this case may correspond to the sector 4, wherein PWM signals for measuring current may be output to the W phase and the V phase in the sector 4 and since the effective voltage vectors are 011 and 001, the currents −I_{U} and I_{W} may be measured and I_{V} may be calculated through the sum of the three phases.

Referring to FIG. 4E, an order of PWM duty lengths may be determined in the order of W phase, U phase, and V phase. Referring to FIG. 2 together, this case may correspond to the sector 5, wherein PWMs signal for measuring current may be output to the W phase and the U phase in the sector 5 and since the effective voltage vectors are 101 and 001, the currents −Iᵥ and I_{w} may be measured and I_{U} may be calculated through the sum of the three phases.

Referring to FIG. 4F, an order of PWM duty lengths may be determined in the order of U-phase, W-phase, and V-phase. Referring to FIG. 2 together, this case may correspond to the sector 6, wherein PWM signals for measuring current may be output to the U-phase and the W-phase in the sector 6 and since effective voltage vectors are 101 and 100, the currents −Iᵥ and I_{U} may be measured and I_{V} may be calculated through the sum of the three phases.

The table below shows the phase current measured by a single current sensor according to the effective voltage vector.

TABLE 1

| | Phase Current Measured by a |
|---|---|
| Effective Voltage Vector | Single Current Sensor |
| 100 | I_{U} |
| 110 | −I_{W} |
| 010 | I_{V} |
| 011 | −I_{U} |
| 001 | I_{W} |
| 101 | −I_{V} |

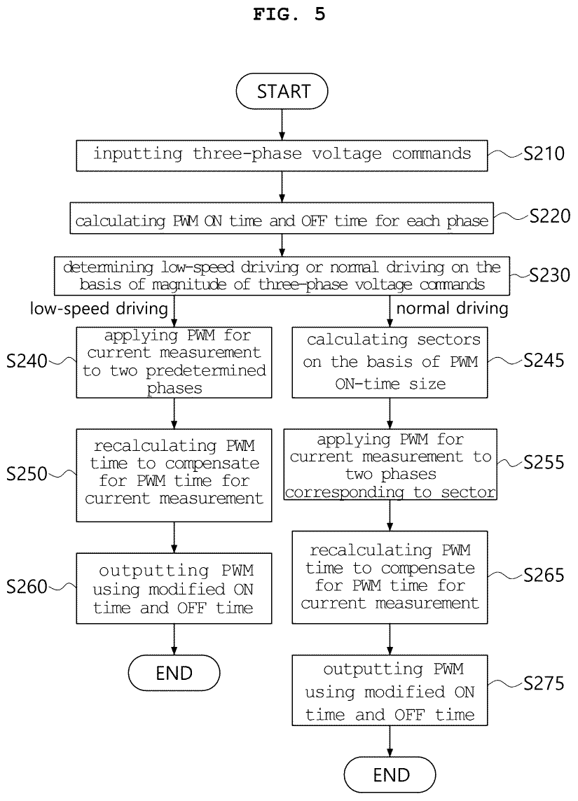

According to an exemplary embodiment of the present disclosure, the motor driving method may be divided into normal driving and low-speed driving, and the normal driving and low-speed driving can be distinguished on the basis of a predetermined speed. In this case, for the normal driving method, PWM signal application and correction may be performed on the basis of the PWM duty ratio of each phase in accordance with FIGS. 4A to 4F. In addition, in the case of the low-speed driving method, the PWM duty application for current sensing may be applied only to the U-phase and the V-phase regardless of the PWM duty ratio of each phase as shown in FIG. 4A. FIG. 5 is a view illustrating a method of applying and correcting PWM signals in a low-speed driving mode and a normal driving mode according to an exemplary embodiment of the present disclosure.

Referring to FIG. 5, in steps S210 and S220, the three-phase motor control system according to an exemplary embodiment of the present disclosure may calculate a PWM duty ratio of each phase on the basis of the carrier signal of the up-counter method and the three-phase voltage command.

In the step S230, the three-phase motor control system according to an exemplary embodiment of the present disclosure may distinguish between a low-speed driving mode and a normal driving mode on the basis of a magnitude of the three-phase voltage commands.

According to an exemplary embodiment of the present disclosure, the normal driving and low-speed driving may be distinguished on the basis of a magnitude of V_{mag}. For example, the V_{mag} may represent a voltage magnitude of a voltage vector, which is a value indicating the magnitude of the voltage vector when controlling a three-phase motor using a vector method (e.g., SVPWM, space vector modulation). In this case, when the magnitude of V_{mag} is determined and the magnitude of V_{mag} is smaller than a predetermined threshold value, it may be classified as a low-speed driving mode. In addition, when the magnitude of the V_{mag} is larger than a predetermined threshold value, it may be classified as a normal driving mode.

In the low-speed driving mode, that is, in steps S240, S250, and S260, the PWM duty application for current sensing can be applied only to the U phase and the V phase as shown in FIG. 4A, regardless of the PWM duty ratio of each phase according to the low-speed driving mode in the three-phase motor control system according to an exemplary embodiment of the present disclosure. Specifically, PWM for current measurement may be applied to two predetermined phases in the step 240, the PWM time may be recalculated to compensate for the PWM time for current measurement in the step 250, and the PWM may be output using the modified ON time and OFF time in the step 260. In this case, since there is no change in the PWM time in the current non-detection section, there is an advantage in that the noise problem occurring therefrom is solved.

In the normal driving mode, that is, in steps S245, S255, S265, and S275, PWM signal application and correction may be performed according to FIGS. 4A to 4F on the basis of the PWM duty ratio of each phase according to the normal driving mode in the three-phase motor control system according to an exemplary embodiment of the present disclosure. Specifically, the sector may be calculated on the basis of a PWM ON-time size in the step 245, PWM for current measurement may be applied to two phases corresponding to the sector in the step 255, the PWM time may be recalculated to compensate for the PWM time for current measurement in the step 265, and the PWM may be output using the modified ON time and OFF time in the step 275. For example, the normal driving mode may represent a method of applying PWM necessary for current measurement to the phase having the longest PWM application time and the phase having an intermediate PWM application time, and in this case, since the current sensing timing is not changed, the current can be measured stably, and there is an advantage in that switching between the low-speed mode and the high-speed mode is facilitated.

The device and/or system described above may be implemented as a hardware component, a software component and/or a combination of a hardware component and/or a software component. The devices and components described in the exemplary embodiments may be implemented using one or more general-purpose computers or special-purpose computers, such as, for example, a processor, a controller, an arithmetic logic unit (ALU), a digital signal processor, a microcomputer, a field programmable gate array (FPGA), a programmable logic unit (PLU), a microprocessor, or any other device capable of executing and responding to instructions. The processing device may perform an operating system (OS) and one or more software applications running on the operating system. In addition, the processing device may access, store, manipulate, process and generate data in response to the execution of software. For convenience of explanation, the processing device has been described as being implemented with a single unit, but, it will be understood by those skilled in the art that the processing device may include multiple processing elements and/or multiple types of processing elements. For example, the processing device may include multiple processors or one processor and one controller. In addition, other processing configurations, such as parallel processors, may be also possible.

Although the exemplary embodiments have been explained with reference to limited exemplary embodiments and drawings, it will be understood by those skilled in the art that various modifications and variations can be possible from the foregoing description. For example, even when the described techniques are performed in a different order than described, and/or components of the described systems, structures, devices, and circuits are combined or integrated in a form different from that described, or are replaced or substituted with other components or equivalents, it is possible to achieve appropriate results. Therefore, other implementations, other exemplary embodiments, and equivalents to the claims also fall within the scope of the following claims.

What is claimed is:

1. A method for measuring current using a single current sensor in a three-phase motor control system, the method comprising:
calculating a PWM duty ratio of each phase on the basis of a carrier signal of an up-counter method and a three-phase voltage command;
applying a PWM signal to each phase for a predetermined measurement time at a start time of the carrier signal on the basis of the PWM duty ratio of each phase; and
correcting the PWM signal of each phase for a predetermined correction time according to the predetermined measurement time within one PWM cycle.

2. The method of claim 1, wherein the applying the PWM signal comprises applying the PWM signal to a first phase having the longest duty length based on the PWM duty ratio of each phase for a time equal to twice a predetermined minimum current measurement time at the start time of the carrier signal.

3. The method of claim 2, wherein the correcting the PWM signal comprises not applying a previously scheduled PWM signal to the first phase for a time equal to one multiple of the predetermined minimum current measurement time after the start time of the carrier signal.

4. The method of claim 1, wherein the applying the PWM signal comprises applying the PWM signal to a second phase having an intermediate duty length based on the PWM duty ratio of each phase for a time equal to one multiple of a predetermined minimum current measurement time at the start time of the carrier signal.

5. The method of claim 1, wherein the applying the PWM signal comprises not applying the PWM signal to a third phase having the shortest duty length based on the PWM duty ratio of each phase at the start time of the carrier signal.

6. The method of claim 5, wherein the correcting the PWM signal comprises applying the PWM signal additionally to the third phase for a time equal to one multiple of a predetermined minimum current measurement time after the start time of the carrier signal.
